(19) United States
(12) Patent Application Publication
(10) Pub. No.: US 2025/0098386 A1
(43) Pub. Date: Mar. 20, 2025

(54) LIGHT EMITTING DISPLAY DEVICE

(71) Applicant: LG Display Co., Ltd., Seoul (KR)

(72) Inventors: Young-Kyun MOON, Paju-si (KR); Seong-Soo JANG, Paju-si (KR)

(21) Appl. No.: 18/828,500

(22) Filed: Sep. 9, 2024

Related U.S. Application Data
(60) Provisional application No. 63/598,917, filed on Nov. 14, 2023.

(30) Foreign Application Priority Data
Sep. 18, 2023 (KR) 10-2023-0123909

(51) Int. Cl. H01L 33/62; H01L 33/38; H01L 33/42

(52) U.S. Cl. CPC H10H 20/857; H10H 20/8312; H10H 20/833

(57) ABSTRACT

A light emitting display device can include a first subpixel and a second subpixel disposed on a substrate, a light emitting layer extending across the first and second subpixels, a cathode electrode disposed on the light emitting layer, the cathode electrode extending across the first and second subpixels, a connection electrode disposed between the first subpixel and the second subpixel, a transmission line configured to receive a driving voltage, the transmission line being electrically connected to the connection electrode, which the cathode electrode is electrically connected to the connection electrode via an exposure hole in the light emitting layer. The light emitting device can include a pattern electrode disposed on the connection electrode, the pattern electrode penetrating through the light emitting layer via the exposure hole and contacting the cathode electrode, in which the pattern electrode includes an opaque layer configured to absorb laser light from an infrared laser.

### CROSS-REFERENCE TO RELATED APPLICATIONS

The present application claims priority to Korean Patent Application No. 10-2023-0123909 filed in Republic of Korea, on Sep. 18, 2023, the entirety of which is hereby incorporated by reference into the present application.

### BACKGROUND

### Field of the Invention

The present invention relates to a light emitting display device.

### Discussion of the Related Art

Recently, flat panel display devices having excellent characteristics such as thinness, light weight, and low power consumption have been widely developed and applied to various fields.

Among the flat panel display devices, a light emitting display device uses a light emitting element in which charges are injected into a light emitting layer formed between an anode and a cathode to form pairs of electrons and holes, and then the pairs disappear to emit light.

Recently, the light emitting display device has increased in size, and due to the increase in size, an IR (e.g., current (I)×resistance (R)) rising of a low-potential driving voltage applied to a cathode has become a reality. Due to the IR rising, the low-potential driving voltage varies depending on location, causing a problem of image quality deterioration. For example, a large display device may develop deviations of the low-potential driving voltage Vss supplied to the cathode electrode in different areas of the screen, e.g., the low-potential driving voltage Vss may be non-uniformly applied to different areas, which can impair image quality.

### SUMMARY OF THE DISCLOSURE

An advantage of the present invention is to provide a light emitting display device that can improve image quality by improving an IR rising of a low-potential driving voltage applied to a cathode and applying the low-potential driving voltage uniformly.

Additional features and advantages of the invention will be set forth in the description which follows, and in part will be apparent from the description, or can be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described herein, a light emitting display device includes a substrate on which a display region is defined, the display region including a plurality of subpixels; a transmission line in the display region on the substrate and transmitting a driving voltage; a passivation layer on the transmission line, a first electrode disposed in the subpixel on the passivation layer, and a connection electrode disposed between neighboring subpixels on the passivation layer and connected to the transmission line, a bank including a first opening exposing the first electrode and a second opening exposing the connection electrode, a light emitting layer on the first electrode, the bank, and the connection electrode, and including an exposure hole exposing the connection electrode, and a second electrode on the light emitting layer and contacting the connection electrode through the exposure hole, in which the connection electrode includes a connecting electrode contacting the transmission line through a contact hole formed in the passivation layer, and a pattern electrode on the connecting electrode, located in the exposure hole, and contacting the second electrode, and the pattern electrode includes a first pattern layer which is formed of an opaque metal configured to absorb laser light from an infrared laser.

In another aspect, a light emitting display device includes a substrate on which a display region is defined, the display region including a plurality of subpixels, a transmission line in the display region on the substrate and transmitting a driving voltage, a passivation layer on the transmission line, a first electrode disposed in the subpixel on the passivation layer, and a connecting electrode disposed between neighboring subpixels on the passivation layer and connected to the transmission line through a contact hole formed in the passivation layer, a bank including a first opening exposing the first electrode and a second opening exposing the connecting electrode, a light emitting layer on the first electrode, the bank, and the connecting electrode, and including an exposure hole exposing the connecting electrode, and a second electrode on the light emitting layer and contacting the connecting electrode through the exposure hole, in which the first electrode includes a first transparent conductive layer formed of the same transparent conductive material as the connecting electrode, and an opaque metal layer on the first transparent conductive layer and formed of an opaque metal configured to absorb laser light from an infrared laser.

In another aspect, a light emitting display device includes a substrate on which a display region is defined, the display region including a plurality of subpixels, a transmission line in the display region on the substrate and transmitting a driving voltage, a passivation layer on the transmission line, a first electrode disposed in the subpixel on the passivation layer, and a connection electrode disposed between neighboring subpixels on the passivation layer and connected to the transmission line, a bank covering an edge of the first electrode and an edge of the connection electrode, a light emitting layer on the first electrode, the bank, and the connection electrode, and including an exposure hole exposing the connection electrode, and a second electrode on the light emitting layer and contacting the connection electrode through the exposure hole, in which the connection electrode includes a connecting electrode contacting the transmission line through a contact hole formed in the passivation layer, and the first electrode includes a first transparent conductive layer formed of the same transparent conductive material as the connecting electrode, and an opaque metal layer on the first transparent conductive layer and formed of an opaque metal configured to absorb laser light from an infrared laser.

It is to be understood that both the foregoing general description and the following detailed description are explanatory examples and are intended to provide further explanation of the invention as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a plan view schematically illustrating a light emitting display device according to an embodiment of the present invention;

FIG. 2 is a cross-sectional view taken along a line II-II′ of FIG. 1 according to an embodiment of the present invention;

FIG. 3 is a cross-sectional view taken along a line III-III′ of FIG. 1 according to an embodiment of the present invention;

FIG. 4 is a view schematically illustrating a voltage line and a transmission line for providing a low-potential driving voltage to an inside of a display region according to an embodiment of the present invention;

FIGS. 5 to 12 are cross-sectional views schematically illustrating a method of manufacturing a light emitting display device according to an embodiment of the present invention;

FIG. 13 is a cross-sectional view schematically illustrating a light emitting display device according to another embodiment of the present invention;

FIG. 14 is a cross-sectional view schematically illustrating a light emitting display device according to another embodiment of the present invention;

FIG. 15 is a cross-sectional view illustrating a process of forming an exposure hole in a light emitting layer in manufacturing a light emitting display device according to an embodiment of the present invention; and

FIG. 16 is a cross-sectional view schematically illustrating a light emitting display device according to another embodiment of the present invention.

### DETAILED DESCRIPTION OF THE EMBODIMENTS

Advantages and features of the present invention and methods of achieving them will be apparent with reference to the embodiments described below in detail with the accompanying drawings. However, the present invention is not limited to the embodiments disclosed below, but can be realized in a variety of different forms, and only these embodiments allow the present invention to be complete. The present invention is provided to fully inform the scope of the invention to the skilled in the art of the present disclosure, and the present invention can be defined by the scope of the claims.

The shapes, sizes, proportions, angles, numbers, and the like disclosed in the drawings for explaining the embodiments of the present invention are illustrative, and the present invention is not limited to the illustrated matters. The same reference numerals refer to the same components throughout the description.

Furthermore, in describing the present invention, if it is determined that a detailed description of the related known technology unnecessarily obscure the subject matter of the present invention, the detailed description thereof can be omitted. When “comprising,” “including,” “having,” “consisting,” and the like are used in this invention, other parts can be added unless ‘only’ is used. When a component is expressed in the singular, situations including the plural are included unless specific statement is described.

In interpreting the components, even if there is no separate explicit description, it is interpreted as including a margin range.

In the situation of a description of a positional relationship, for example, when the positional relationship of two parts is described as “on,” “over,” “above,” “below,” “beside,” “under,” and the like, one or more other parts can be positioned between such two parts unless “right” or ‘directly’ is used.

In the situation of a description of a temporal relationship, for example, when a temporal precedence is described as “after,” “following,” “before,” and the like, situations that are not continuous can be included unless “directly” or “immediately” is used. Also, the term “can” includes all meanings and definitions of the term “may.”

In describing components of the present invention, terms such as first, second and the like can be used. These terms are only for distinguishing the components from other components, and an essence, order, order, or number of the components is not limited by the terms.

Respective features of various embodiments of the present invention can be partially or wholly connected to or combined with each other and can be technically interlocked and driven variously, and respective embodiments can be independently implemented from each other or can be implemented together with a related relationship.

Hereinafter, embodiments of the present invention are described in detail with reference to the drawings. In this regard, all the components of each device or apparatus according to all embodiments of the present disclosure are operatively coupled and coupled. Meanwhile, in the following embodiments, the same and like reference numerals are assigned to the same and like components, and detailed descriptions thereof can be omitted.

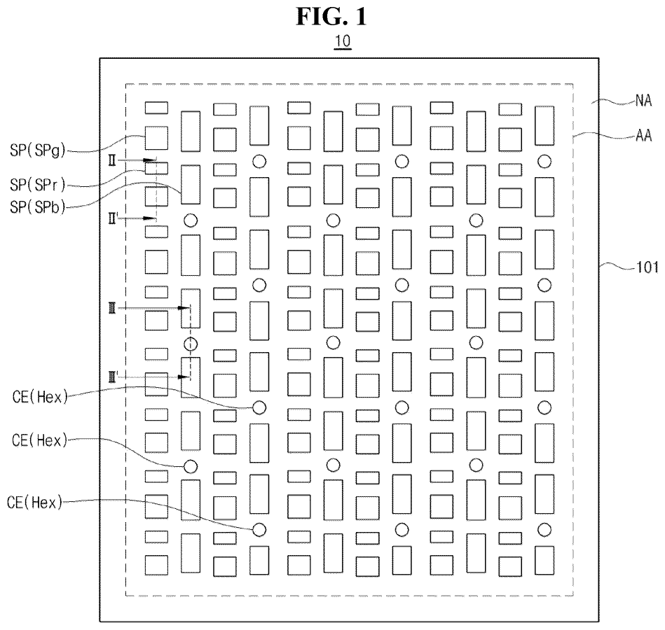

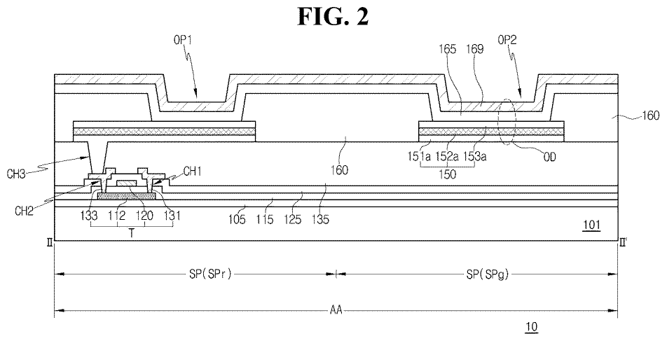

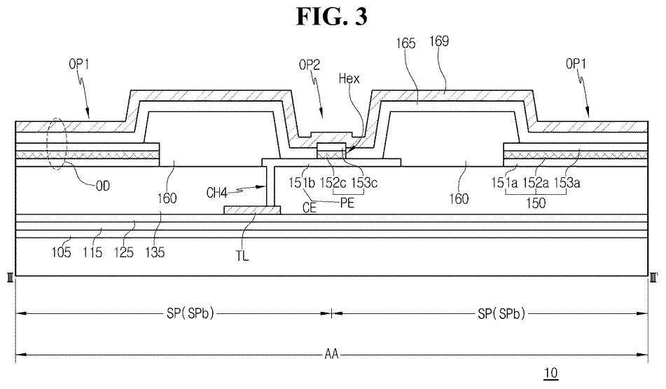

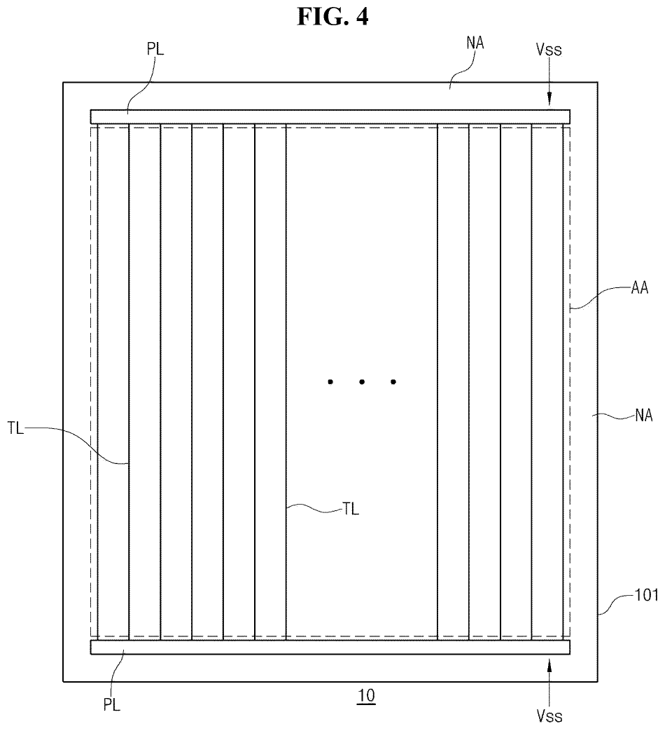

FIGS. 1 and 2 are plan views schematically illustrating an arrangement of subpixels and an arrangement of color filter patterns of a light emitting display device according to a first embodiment of the present invention, respectively. FIGS. 3 and 4 are views enlarging regions of FIGS. 1 and 2, respectively.

Particularly, FIG. 1 is a plan view schematically illustrating a light emitting display device according to a first embodiment of the present invention. FIG. 2 is a cross-sectional view taken along a line II-II′ of FIG. 1, and FIG. 3 is a cross-sectional view taken along a line III-III′ of FIG. 1.

Prior to a detailed description, the light emitting display device 10 according to this embodiment of the present invention can be any one of all types of display devices that display images with a light emitting diode OD which is a self-luminescent emitting element.

In this embodiment, for convenience of explanation, a situation where an organic light emitting display device is used as the light emitting display device 10 is taken as an example.

In addition, the light emitting display device 10 can be a top emission type display device or a bottom emission type display device. In this embodiment, for convenience of explanation, the top emission type light emitting display device 10 is taken as an example.

Referring to FIGS. 1 to 3, in the light emitting display device 10 (or a light emitting display panel of the light emitting display device 10) of this embodiment, a display region (or active area) AA for displaying an image and a non-display region (or non-active area) NA disposed around the display region AA can be defined.

The display region AA can include a plurality of subpixels SP arranged along a plurality of row lines (or horizontal lines) and a plurality of column lines (or vertical lines) on the substrate 101. Also, a plurality of gate lines extending along a row direction (or horizontal direction or first direction) and a plurality of gate lines extending along a column direction (or vertical direction or second direction) can be formed on the substrate 101. Each subpixel SP can be connected to the corresponding gate line and data line.

The plurality of subpixels SP can include subpixels SP of different colors constituting a pixel which is a unit for displaying a color image. In this regard, the plurality of subpixels SP can include three subpixels that display first, second, and third colors, for example, red (R), green (G), and blue (B) subpixels SPr, SPg, and SPb that display red (R), green (G), and blue (B), respectively.

The R, G, and B subpixels SPr, SPg, and SPb can be arranged in various manners. For example, as shown in FIG. 1, the R and G subpixels SPr and SPg can be arranged alternately in the same column line, and the B subpixels SPb can be arranged in a neighboring (or adjacent) column line. Alternatively, the R, G, and B subpixels SPr, SPg, and SPb can be arranged in a different manner. In this embodiment, for convenience of explanation, the situation where the R, G, and B subpixels SPr, SPg, and SPb are arranged as shown in FIG. 1 is taken as an example.

Meanwhile, in the light emitting display device 10 of this embodiment, a connection structure can be formed in the display region AA to connect a transmission line (or auxiliary line) TL with a cathode 169 of the light emitting diode OD at multiple positions (or points), and the transmission line TL can transmit a low-potential driving voltage (or low-potential power voltage) Vss which is a driving voltage applied to a cathode 169.

As such, by implementing the connection structure of the low-potential driving voltage Vss within the display region AA, an IR rising for the low-potential driving voltage Vss can be improved (e.g., current (I)×resistance (R)=voltage (V)). Accordingly, since a uniform low-potential driving voltage Vss can be applied to the cathode 169, image quality can be improved. In other words, due to the connection structure, deviations of the low-potential driving voltage Vss in different areas of the screen can be prevented or avoided, and the low-potential driving voltage Vss can be uniformly applied across the screen and good image quality can be provided even for very large display devices.

The connection structure of the low-potential driving voltage Vss within the display region AA is be described in more detail below.

FIGS. 2 and 3 are views schematically illustrating a cross-sectional structure of the light emitting display device 10 of this embodiment. FIG. 2 schematically shows the cross-sectional structure of the R and G subpixels SPr and SPg, and FIG. 3 schematically shows the connection structure of the low-potential driving voltage Vss between the neighboring subpixels SP, for example, the neighboring B subpixels SPb. Meanwhile, for convenience of explanation, FIG. 2 shows one thin film transistor T connected to the light emitting diode OD in the R subpixel SPr.

Referring to FIGS. 2 and 3, the thin film transistor T and the light emitting diode OD can be formed on the substrate 101 in each subpixel SP. Also, a plurality of thin film transistors, including the thin film transistor T, can be formed in each subpixel SP and at least one capacitor can be further formed in each subpixel SP.

In more detail, a semiconductor layer 112 can be formed on the substrate 101. The semiconductor layer 112 can be formed of amorphous silicon, polycrystalline silicon, or an oxide semiconductor material, but not limited thereto.

The semiconductor layer 112 can include a channel region at a center and source and drain regions on both sides.

Meanwhile, a buffer layer 105 can be formed on the substrate 101 and below the semiconductor layer 112.

A gate insulating layer 115 can be formed on the semiconductor layer 112 as an insulating layer formed of an insulating material. The gate insulating layer 115 can be formed of an inorganic insulating material such as silicon oxide or silicon nitride, but not limited thereto.

A gate electrode 120 formed of a conductive material such as metal can be formed on the gate insulating layer 115 to correspond to the channel region of the semiconductor layer 112.

The gate line connected to the gate electrode of a switching thin film transistor can be formed on the gate insulating layer 115.

An inter-layered insulating layer 125 can be formed on the gate electrode 120 as an insulating layer made of an insulating material.

The inter-layered insulating layer 125 can be formed of an inorganic insulating material such as silicon oxide or silicon nitride, or can be formed of an organic insulating material such as benzocyclobutene or photo acryl, but not limited thereto.

The inter-layered insulating layer 125 and the gate insulating layer 115 can be provided with a first contact hole CH1 and a second contact hole CH2 that expose the source region and the drain region of the semiconductor layer 112, respectively.

The first contact hole CH1 and the second contact hole CH2 can be located on both sides of the gate electrode 120 and spaced apart from the gate electrode 120.

A source electrode 131 and a drain electrode 133 formed of a conductive material such as metal can be formed on the inter-layered insulating layer 125.

On the inter-layered insulating layer 125, the data line can be formed that crosses the gate line and is connected to the source electrode of the switching thin film transistor.

In addition, on the inter-layered insulating layer 125, the transmission line TL formed in the same process as the source electrode 131, the drain electrode 133, and the data line can be formed. The transmission line TL can transmit the low-potential driving voltage Vss.

Meanwhile, as another example, the transmission line TL can be formed of the same material as and in the same process as the gate electrode 120 and the gate line. As another example, the transmission line TL can be formed at a different layer from and in a different process from the source electrode 131, the drain electrode 133, and the gate electrode 120.

The transmission line TL can be connected to a voltage line (PL in FIG. 4) that is placed in the non-display region NA and directly receives the low-potential driving voltage Vss from an outside. This can refer to FIG. 4.

FIG. 4 is a view schematically illustrating a voltage line and a transmission line for uniformly providing a low-potential driving voltage to an inside of a display region according to a first embodiment of the present invention.

Referring to FIG. 4, for example, the voltage lines PL can be disposed on both sides of the display region AA, for example, on the upper and lower sides of the display region AA in FIG. 4. The voltage line PL can receive the low-potential driving voltage Vss output from an external power circuit.

For example, a plurality of transmission lines TL can be formed to extend along the column direction. The transmission line TL can traverse the display region AA, and one end of the transmission line TL can be connected to the voltage line PL disposed on the upper side, and the other end of the transmission line TL can be connected to the voltage line PL disposed on the lower side.

As such, the plurality of transmission lines TL can be connected to the voltage lines PL on both sides to transmit the low-potential driving voltage Vss into the display region AA. Also, a width of each of the voltage lines PL can be greater than a width of each of the plurality of transmission lines TL.

Meanwhile, as another example, the transmission line TL can be formed to extend along the row direction parallel to the gate line. As another example, the transmission line TL can be configured in a mesh form by extending along the column direction and the row direction. Similarly, the voltage lines PL can have a mesh form configuration, but embodiments are not limited thereto.

Referring again to FIGS. 2 and 3, the source electrode 131 and the drain electrode 133 can be spaced apart from each other with the gate electrode 120 located therebetween, and can contact the source region and drain region of the semiconductor layer 112 through the first contact hole CH1 and the second contact hole CH2, respectively.

The semiconductor layer 112, the gate electrode 120, the source electrode 131, and the drain electrode 133 configured as above can form the thin film transistor T.

As another example, the thin film transistor T can have an inverted staggered structure in which the gate electrode 120 is located below the semiconductor layer 112 and the source electrode 131 and the drain electrode 133 are located on the semiconductor layer 112.

A passivation layer (or overcoat layer) 135 as an insulating layer made of an insulating material can be formed on the source electrode 131, the drain electrode 133, and the transmission line TL.

The passivation layer 135 can be formed of at least one of an inorganic insulating material, such as silicon oxide or silicon nitride and an organic insulating material such as benzocyclobutene or photo acryl, but not limited thereto.

A third contact hole (or drain contact hole) CH3 exposing the drain electrode 133 can be formed in the passivation layer 135.

A fourth contact hole CH4 exposing the transmission line TL can be formed in the passivation layer 135.

An anode (or first electrode) 150 can be formed on the passivation layer 135 for each subpixel SP. The anode 150 can contact the drain electrode 133 through the third contact hole CH3.

The anode 150 can be formed of an opaque metal material and can have high reflectance characteristics. For example, the anode 150 can include at least one of Ag, Al, Mo, Ti, APC (Al—Pd—Cu) alloy, but not limited thereto.

The anode 150 can be formed in a multi-layered structure. In this regard, for example, the anode 150 can be formed in a multi-layered structure in which a transparent conductive material (e.g., ITO, IZO, IZTO, etc.) is stacked on and below the above-described opaque metal material.

For example, as shown in FIGS. 2 and 3, the anode 150 can be formed in a three-layered structure, including a first transparent conductive layer 151a as a lower layer, a second transparent conductive layer 153a as an upper layer, and an opaque metal layer 152a interposed between the first and second transparent conductive layers 151a and 153a.

Meanwhile, a connection electrode CE can be located on the passivation layer 135 and formed as the same material as and in the same process as the anode 150. The connection electrode CE can be uniformly distributed at multiple positions within the display region AA. For example, the connection electrode CE can be on a same layer as the anode 150.

The connection electrode CE can have a structure that connects, for example, the transmission line TL transmitting the low-potential driving voltage Vss with the cathode 169 of the light emitting diode OD.

The connection electrode CE can be formed in a stacked structure substantially the same as the anode 150.

In this regard, for example, the connection electrode CE can include a connecting electrode (or contact electrode) 151b and a pattern electrode PE formed in an island pattern shape on the connecting electrode 151b. The pattern electrode PE can have an island-shape.

Here, the connecting electrode 151b can be formed of the same transparent conductive material as the first transparent electrode layer 151a of the anode 150. The connecting electrode 151b can contact the transmission line TL through the fourth contact hole CH4.

The island-shaped pattern electrode PE can be formed to, for example, have a smaller size (or smaller width or smaller area) than the connecting electrode 151b.

The pattern electrode PE can include, for example, a first pattern layer 152c made of the same opaque metal as the opaque metal layer 152a of the anode 150, and a second pattern layer 153c made of the same transparent conductive material as the second transparent conductive layer 153a of the anode 150.

The connection electrode CE can be formed in a non-emission region between the neighboring subpixels SP in order to connect the transmission line PL with the cathode 169 of the light emitting diode OD. In this embodiment, for convenience of explanation, a situation where the connection electrode CE is formed in the non-emission region between the neighboring B subpixels SPb is taken as an example.

A bank 160 can be formed on the anode 150 and the connection electrode CE and be formed along a boundary of each subpixel SP (or a boundary between the neighboring subpixels SP).

The bank 160 can be formed to cover edges of the anode 150 disposed in each subpixel SP.

In addition, the bank 160 can be formed to cover edges of the connection electrode CE, or more specifically, edges of the connecting electrode 151b of the connection electrode CE.

The bank 160 can be formed of, for example, at least one of acrylic resin, epoxy resin, phenol resin, polyamide-based resin, polyimide-based resin, unsaturated polyester-based resin, polyphenylene-based resin, polyphenylene sulfide-based resin, benzocyclobutene and photoresist, but not limited thereto.

The bank 160 configured as above can have a first opening OP1 exposing the anode 150 of each subpixel SP. Light can be emitted from each subpixel SP through the first opening OP1, so that the first opening OP1 can substantially define an emission region of each subpixel SP.

In addition, the bank 160 can have a second opening OP2 exposing the connection electrode CE. In this regard, for example, the second opening OP2 of the bank 160 can be formed corresponding to the boundary region between the subpixels SP where the connection electrode CE is disposed. The second opening OP2 can be smaller than the first opening OP1. Also, a shape of the second opening OP2 can be different than a shape of the first opening OP1.

For example, this second opening OP2 can expose a portion of the connection electrode CE located inside the edges of the connection electrode 151b and can also expose the entire pattern electrode PE. In other words, the bank 160 can be formed to cover the edges of the connecting electrode 151b while exposing the pattern electrode PE.

The light emitting layer 165 can be continuously formed along a top surface of the anode 150 of each subpixel SP, side and top surfaces of the bank 160, and a top surface of the connection electrode CE. In other words, the light emitting layer 165 can be continuously formed within the display region AA and disposed in the first opening OP1, on the surfaces of the bank 160, and in the second opening OP2. For example, the light emitting layer 165 can be laid down as a common layer.

In each subpixel SP, the light emitting layer 165 can contact the anode 150 exposed through the first opening OP1 of the bank 160.

Meanwhile, in the non-emission region between the neighboring subpixels SP where the connection electrode CE is formed, the light emitting layer 165 can have a form that exposes, for example, the pattern electrode PE of the connection electrode CE. In other words, the light emitting layer 165 can have an exposure hole Hex, which is a hole that exposes the pattern electrode PE upward, by removing a portion of the light emitting layer 165 corresponding to the pattern electrode PE.

Regarding the exposure hole Hex, for example, after the light emitting layer 165 is formed to cover both the connecting electrode 151b and the pattern electrode PE, when laser light from an infrared laser is irradiated to the pattern electrode PE, the first pattern layer 152c made of the opaque metal in the pattern electrode PE absorbs the laser light from the infrared laser and undergoes a Joule heating, and due to this heat generated by the first pattern layer 152c, a portion of the light emitting layer 165 covering the pattern electrode PE can be vaporized and removed.

Accordingly, the exposure hole Hex having substantially the same shape (more specifically, the same planar shape) as the pattern electrode PE can be formed in the light emitting layer 165.

As such, in this embodiment, the exposure hole Hex of the light emitting layer 165 can be formed by heating the first pattern layer 152c made of the opaque metal that has a property of absorbing laser light from the infrared laser.

Accordingly, the exposure hole Hex of the light emitting layer 165 can be formed to be substantially aligned (or matched) exactly with the pattern electrode PE. Here, depending on a heating temperature of the first pattern layer 152c according to an energy density of the irradiated infrared laser light, the exposure hole Hex can have a size (or width or area) equal to or greater than that of the pattern electrode PE. For example, the pattern electrode PE can penetrate or extend all the way through the light emitting layer 165, and secure electrical contact can be made between sides of the pattern electrode PE and the light emitting layer 165, but embodiments are not limited thereto.

As above, in this embodiment, in forming the exposure hole Hex, the process of vaporizing the light emitting layer 165 is carried out using the Joule heating effect caused by the infrared laser irradiation, so that the light emitting layer 165 can expose the pattern electrode PE while surrounding an outer circumference of the pattern electrode PE without substantial processing errors.

In addition, as the exposure hole Hex is formed through the Joule heating effect, the portion of the light emitting layer 165 around the pattern electrode PE can have a thickness (or height) smaller than that of the pattern electrode PE. Accordingly, the pattern electrode PE can have a shape that protrudes upward from the portion of the light emitting layer 165 around the pattern electrode PE. In this way, secure electrical contact can be made between the pattern electrode PE and the cathode 169.

Meanwhile, the portion of the light emitting layer 165 located within the second opening OP2, or more specifically, the portion of the light emitting layer 165 located on the connecting electrode 151b can have a substantially uniform thickness. In other words, a top surface of the light emitting layer 165 located on the connecting electrode 151b can be substantially flat.

In addition, an inner surface of the light emitting layer 165 around the pattern electrode PE (e.g., the inner surface of the light emitting layer 165 that defines the exposure hole Hex) can have an inclination close to vertical. For example, the inner surface of the light emitting layer 165 around the pattern electrode PE can have an inclination of about 70 degrees to 90 degrees.

A cathode (or second electrode) 169 can be formed on the light emitting layer 165 in which the exposure hole Hex is formed.

The cathode 169 can be formed substantially continuously (or integrally) within the display region AA. In other words, the cathode 169 can be formed to correspond to all of the subpixels SP disposed in the display region AA. For example, the cathode 169 can be laid down as a common layer.

The cathode 169 can be formed of a transparent electrode with transparent characteristics, and in this situation, the cathode 169 can be formed of a transparent conductive material such as ITO.

Meanwhile, in the situation of implementing a micro cavity effect, the cathode 169 can be configured to include a transflective electrode layer with transflective characteristics, and can be formed in a multi-layered structure including the transflective electrode layer. The transflective electrode layer of the cathode 169 can be formed of a metal such as Mg, Ag, or an alloy of Mg and Ag, but not limited thereto. Such the metal can be formed to be thin enough to implement transflective properties.

The anode 150, the light emitting layer 165, and the cathode 169 arranged as above in the first opening OP1 in each subpixel SP can constitute the light emitting diode OD.

The light emitting diode OD can emit light from the light emitting layer 165 interposed between the anode 150 and the cathode 169, and the light emitted in this way can travel upward and be output.

Meanwhile, in this embodiment, the cathode 169 can contact the connection electrode CE, more specifically, the cathode 169 can contact the pattern electrode PE at the second opening OP2. Accordingly, the cathode 169 can be electrically connected to the transmission line TL through the connection electrode CE configured with the pattern electrode PE and the connecting electrode 151b. In this way, a secure electrical connection can be formed between the cathode 169 and the connection electrode CE.

Accordingly, the low-potential driving voltage Vss applied to the transmission line TL can be provided to the cathode 169 through the connection electrode CE.

As such, in this embodiment, the structure for connecting the transmission line TL and the cathode 169 can be implemented by forming the connection electrode CE in the boundary region between the neighboring subpixels SP within the display region AA, and this connection structure can be uniformly (or evenly) distributed at multiple positions within the display region AA. For example, the connections between a plurality of connection electrodes CE and the cathode 169 can prevent any voltage deviations for the low-potential driving voltage Vss provided to the cathode 169, and a uniform and stable low-potential driving voltage Vss can be supplied to all of the sub-pixels even when the display is very large.

Accordingly, the low-potential driving voltage Vss can be provided to the cathode 169 through the multiple connection structures formed at the multiple positions within the display region AA.

Accordingly, the above described configuration can minimize or prevent the problem of when the low-potential driving voltage (Vss) is provided to both ends of the cathode 169 (e.g., opposite ends of a large display screen), a resistance increases toward the inside of the display region AA, thus an IR rising is caused, and thus the low-potential driving voltage Vss becomes non-uniform depending on positions.

In other words, in this embodiment, the low-potential driving voltage Vss can be transmitted into the display region AA through the transmission wiring TL with low resistance characteristics, and the low-potential driving voltage Vss can be applied to the cathode 169 through the connection structures configured at the multiple positions within the display region AA (e.g., even at the center of the display region AA). Accordingly, even in the direction inside the display region AA, the increase in resistance can be minimized and the IR rising can be substantially minimized. Therefore, a substantially uniform low-potential driving voltage Vss can be applied to the entire cathode 169. Accordingly, image quality degradation due to positional deviation of the low-potential driving voltage Vss can be improved.

In addition, as mentioned above, in this embodiment, in implementing the connection structure of the low-potential driving voltage Vss, laser light from the infrared laser can be irradiated to the pattern electrode PE of the connection electrode CE, and through the Joule heating effect by the infrared laser irradiation, the portion of the light emitting layer 165 covering the pattern electrode PE can be removed to form the exposure hole Hex exposing the pattern electrode PE, and the cathode 169 can be brought into contact with the exposed pattern electrode PE. In this way, manufacturing efficiency and production yields can be improved.

As a result, the contact area between the connection electrode CE and the cathode 169 can be optimized as desired without substantial processing errors.

Accordingly, an aperture ratio of the light emitting display device 10 can be maximized.

In this regard, in a comparative example of a so-called laser drilling method, in which the connection electrode CE is formed in the same stacked structure as the anode 150 without the pattern electrode PE, and the exposure hole Hex is formed to expose the connection electrode CE by directly irradiating an ultraviolet laser light/beam or green laser light/beam to the light emitting layer 165, due to a laser irradiation equipment, laser beam size, or the like, a minimum size of the exposure hole Hex that can be implemented is 10 um or more, and a tolerance of 10 um or more needs to be reflected. Accordingly, in the comparative example, an area of at least 30 um is required to form the exposure hole Hex, and as a result, the area of the exposure hole Hex increases, which takes up more space and causes restrictions on a number of the exposure holes Hex, and can made it more difficult to provide higher resolutions.

On the other hand, in this embodiment, the exposure hole Hex of a size corresponding to the pattern electrode PE can be formed through the Joule heating effect. Therefore, it is not substantially affected by the laser irradiation equipment, laser beam size, or the like, so that the exposure hole Hex of a size smaller than 10 um can be formed, and there is no need to consider tolerance. Accordingly, the area of the exposed hole Hex (e.g., the contact area) can be minimized, thereby maximizing the aperture ratio. Moreover, a number of the exposure holes Hex (e.g., the contact positions) can be increased, so the low-potential driving voltage Vss can be made more uniform.

In addition, according to this embodiment, in the light-emitting display device 10, occurrence of a residual film of the light emitting layer 165 in a laser processing region can be prevented, and a substantially zero level can be achieved.

In this regard, in the above-mentioned comparative example, a level of occurrence of a residual film of the light emitting layer 165 in the laser processing region increases due to a Gaussian profile of a laser, so that the light emitting layer 165 is not completely removed within the exposure hole Hex and a residual film can exist. In other words, the laser light/beam may not be able to cut a hole with clean, sharp edges.

On the other hand, in this embodiment, since the Joule heating effect is used, a hole can be melted through the light emitting layer 165 that more exactly matches the size and edges of the pattern electrode PE and an occurrence of a residual film can be substantially prevented in the laser processing region, so that substantially no residual film exists in the exposure hole Hex. Accordingly, it is possible to improve reduction in contact area and increase in contact resistance caused by the residual film. In other words, instance of cutting away a hole through the light emitting layer 165 with a laser by itself, a better defined hole can be made in the light emitting layer 165 by heating the pattern electrode PE with a laser and using the heated light emitting layer 165 to melt a hole through the light emitting layer 165 that matches the shape of the pattern electrode PE.

In addition, according to this embodiment, it is possible to prevent defects in layers located below the light emitting layer 165 in the light emitting display device 10.

In this regard, in the above-mentioned comparative example, an ultraviolet laser light or green laser light is directly irradiated, and such the laser light has a low selectivity for the connection electrode CE and the passivation layer 135 located below the light emitting layer 165, so that the laser light acts on the connection electrode CE and the passivation layer 135 and causes undesirable damage to the connection electrode CE and the passivation layer 135.

On the other hand, in this embodiment, the infrared laser light with a relatively low wavelength band and high selectivity is used. Moreover, as described later, in this embodiment, the infrared laser light can be irradiated from a rear of the substrate 101. Such the infrared laser light acts on the first pattern layer 152c of an opaque metal within the connection electrode CE, and passes through layers disposed above and below the first pattern layer 152c without substantially acting on the layers. Accordingly, it is possible to prevent defects in the layers below the light emitting layer 165.

Furthermore, as described later, in this embodiment, with the substrate 101 turned over and the light emitting layer 165 facing a ground or a downward direction, laser light from the infrared laser is irradiated from the rear of the substrate 101, e.g., from above, and a removed material of the light emitting layer 165 falls to a bottom of a process chamber. If the infrared laser light is irradiated from a front of the substrate 101, e.g., from below, a problem occurs in which the material of the light emitting layer 165 that is removed and falls on the bottom of the process chamber interferes with laser irradiation. In other words, the first pattern layer 152c can be heated by the laser and used similar to a hole punch to efficiently cut a hole away from the light emitting layer 165 and the cut away piece can conveniently fall away to the ground. Therefore, according to the rear irradiation of laser of this embodiment, interference with laser irradiation is prevented and the laser process can proceed smoothly.

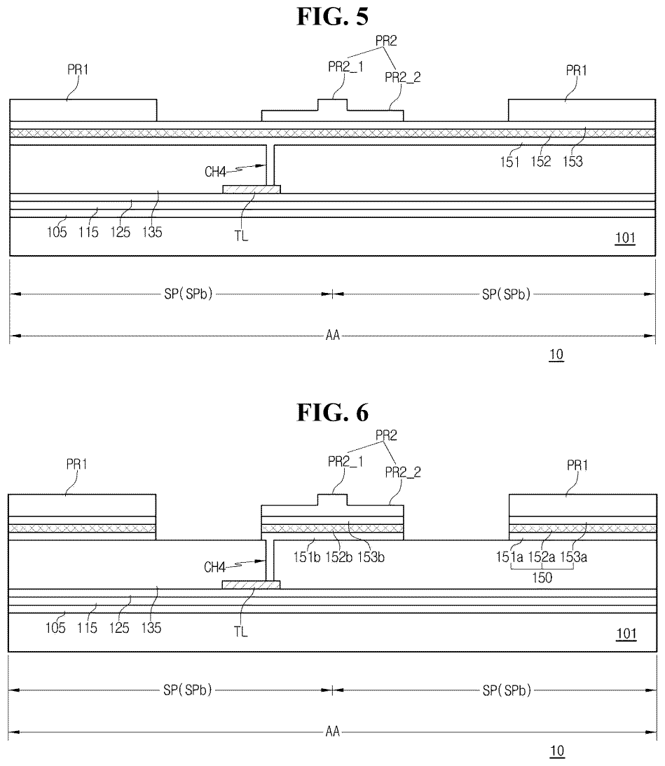

Hereinafter, with reference to FIGS. 5 to 12, a method of manufacturing the light emitting display device according to the first embodiment of the present invention is described.

First, referring to FIG. 5, a plurality of conductive layers can be formed on the passivation layer 135 to form the anode 150 and the connection electrode CE. For example, a first transparent conductive material layer 151, an opaque metal material layer 152, and a second transparent conductive material layer 153 can be sequentially deposited on the passivation layer 135.

Thereafter, a photoresist can be coated on the second transparent conductive material layer 153 and be patterned using a halftone mask to form a first photoresist pattern PR1 corresponding to the subpixel SP, and a second photoresist pattern PR2 corresponding to the boundary between the neighboring subpixels SP.

The first photoresist pattern PR1 can have a first thickness. The second photoresist pattern PR2 can be configured with a first pattern part PR2_1 having a first thickness and a second pattern part PR2_2 outside the first pattern part PR2_2 having a second thickness smaller than the first thickness.

Next, referring to FIG. 6, a first etching process can be performed using the first and second photoresist patterns PR1 and PR2 as an etching mask to each the first transparent conductive material layer 151, the opaque metal material layer 152, and the second transparent conductive material layer 153.

Accordingly, below the first photoresist pattern PR1, an anode 150 can be formed and be configured with a first transparent conductive layer 151a, an opaque metal layer 152a, and a second transparent conductive layer 153a which are the patterned first transparent conductive material layer 151, opaque metal material layer 152, and second transparent conductive material layer 153, respectively.

In addition, below the second photoresist pattern PR2, a connecting electrode 151b, an opaque metal pattern layer 152b and a second transparent conductive pattern layer 153b, which are the patterned first transparent conductive material layer 151, opaque metal material layer 152, and second transparent conductive material layer 153, respectively, can be formed.

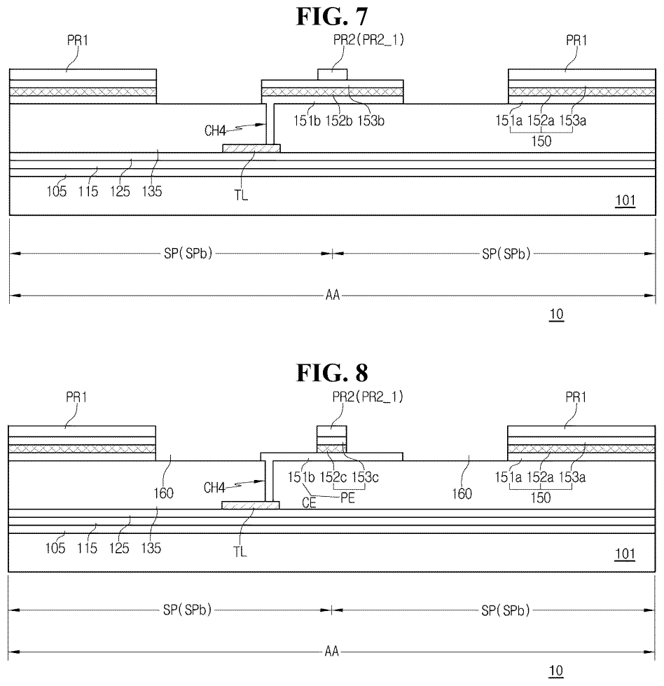

Next, referring to FIG. 7, an ashing process can be performed for the first and second photoresist patterns PR1 and PR2.

Accordingly, the first photoresist pattern PR1 can be partially removed in a thickness direction and remain on the anode 150.

In addition, regarding the second photoresist pattern PR2, the thin second pattern part PR2_2 can be completely removed, and the first pattern part PR2_1 can be partially removed in a thickness direction and remain in place, in the same manner as the first photoresist pattern PR1. As a result, the second photoresist pattern PR2 can be configured with the first pattern part PR2_1, and the second transparent conductive pattern layer 153b located below the second pattern part PR2_2 can be exposed.

Next, referring to FIG. 8, a second etching process can be performed using the ashed first and second photoresist patterns PR1 and PR2 as an etching mask to etch the second transparent conductive pattern layer 153b and the opaque metal pattern layer 152b located below the second photoresist pattern PR2.

Accordingly, below the second photoresist pattern PR2, a pattern electrode PE can be formed and configured with a second pattern layer 153c and a first pattern layer 152c which are the patterned second transparent conductive pattern layer 153b and opaque metal pattern layer 152b, respectively.

The pattern electrode PE and the connecting electrode 151b can constitute a connection electrode CE.

Through the above processes, the anode 150 can be formed in each subpixel SP, and the connection electrode CE can be formed at the boundary between the neighboring subpixels SP.

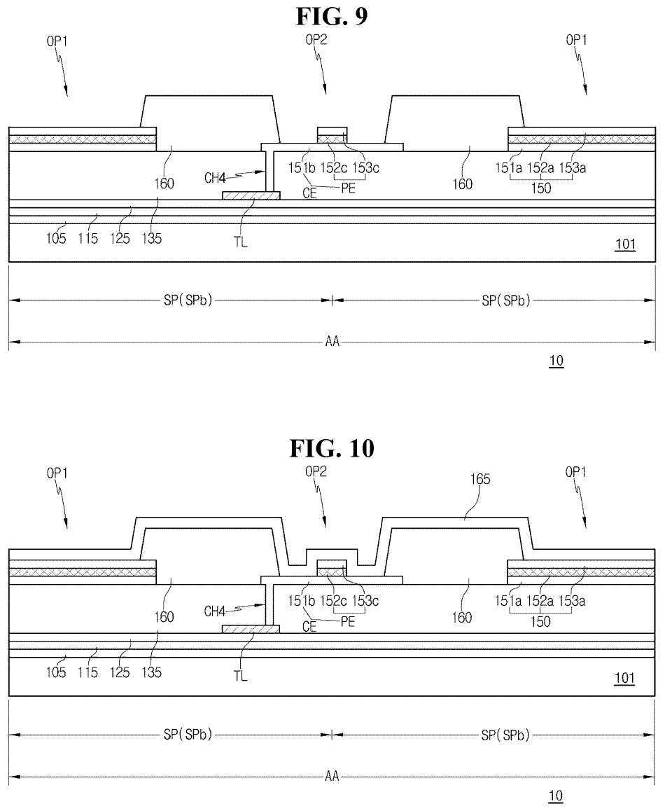

Next, referring to FIG. 9, a bank 160 can be formed on the substrate 101 on which the anode 150 and the connection electrode CE are formed.

The bank 160 can include a first opening OP1 corresponding to the subpixel SP and defining an emission region, and a second opening OP2 corresponding to a boundary region (or non-emission region) between the subpixels SP where the connection electrode CE is formed.

The anode 150 can be exposed upward through the first opening OP1. In addition, the connection electrode CE can be exposed upward through the second opening OP2. Here, the pattern electrode PE of the connection electrode CE can have substantially all of its top and side surfaces exposed.

Next, referring to FIG. 10, a light emitting layer 165 can be formed on the substrate 101 on which the bank 160 is formed. The light emitting layer 165 can be formed substantially continuously over the entire surface of the substrate 101 as a common layer.

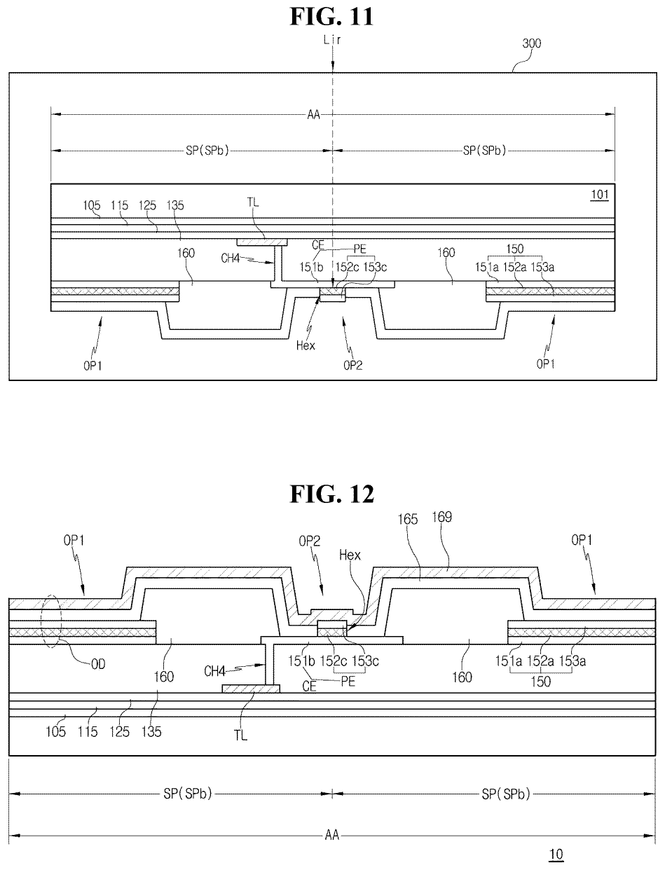

Next, referring to FIG. 11, the substrate 101 can be turned upside down so that the light emitting layer 165 faces a ground or a downward direction. In FIG. 11, for convenience of explanation, a process chamber 300 is shown in which the substrate 101 having the light-emitting layer 165 is placed in an internal space. At this time, the process chamber 300 can be, for example, a process chamber for depositing the light emitting layer 165 in FIG. 10.

In the state in which the substrate 101 is turned over, an infrared laser Lir can be irradiated toward the substrate 101 from above the process chamber 300. In other words, the infrared laser (or infrared laser light) Lir can be irradiated from the rear of the substrate 101.

The infrared laser light Lir can be irradiated to the pattern electrode PE of the connection electrode CE. The infrared laser light Lir can have a high selectivity. In other words, it can have a property of being absorbed by the first pattern layer 152c of an opaque metal in the pattern electrode PE, and of being transmitted without being substantially absorbed by the layers stacked above and below the first pattern layer 152c.

Accordingly, the first pattern layer 152c can be Joule-heated by the infrared laser Lir, so that the portion of the light emitting layer 165 covering the pattern electrode PE can be vaporized by the heat and removed. As a result, an exposure hole Hex in a shape aligned with the pattern electrode PE can be formed in the light emitting layer 165. For example, the pattern electrode PE can be used as a type of “hole punch” to punch or melt a hole through the light emitting layer 165 when heated by the laser.

In implementing the Joule heating, the infrared laser light Lir can be set to have a specific energy density. In this regard, for example, under a condition that the infrared laser Lir has a wavelength of 1064 nm, a pulse width of 14 ns, and one shot is made, the energy density of the infrared laser Lir of this embodiment can be set to about 1.0 J/cm² or less.

After forming the exposure hole Hex in the light emitting layer 165 through the laser processing, the substrate 101 can be turned right-side up again (e.g., flipped over again) so that a bottom surface of the substrate 101 faces the ground.

Next, referring to FIG. 12, a cathode 169 can be formed on the substrate 101 on which the light emitting layer 165 having the exposure hole Hex is formed. The cathode 169 can be formed substantially continuously over the entire surface of the substrate 101 as a common layer.

The cathode 169 can contact the pattern electrode PE that is exposed through the exposure hole Hex, so that the cathode 169 can be electrically connected to the transmission line TL through the connection electrode CE. Through the connection structure within the display region AA, the low-potential driving voltage Vss can be provided to the cathode 169.

As above, in this embodiment, the connection electrode CE can be formed of the same material as the anode 150 and in the same process as the anode 150, so that there is no need to proceed with a separate process to form the connection electrode CE, and efficiency of process can be improved.

In addition, after forming the cathode 169, a process of forming an encapsulation layer on the cathode 169 can be performed.

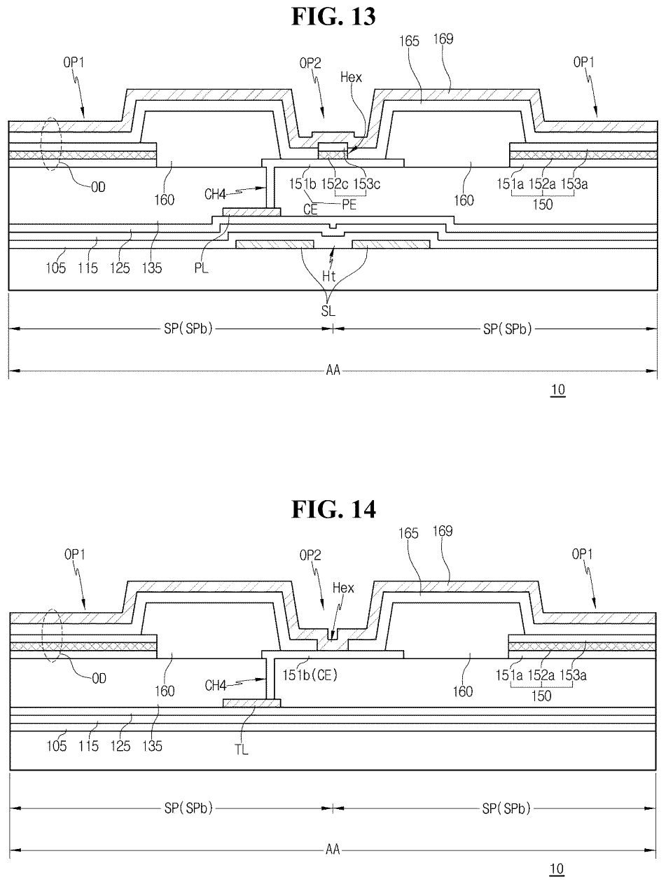

FIG. 13 is a cross-sectional view schematically illustrating a light emitting display device according to a second embodiment of the present invention. FIG. 13 schematically shows a connection structure of a low-potential driving voltage, like FIG. 3 of the first embodiment.

In the following description, detailed descriptions of configurations identical to or similar to those of the above-described first embodiment can be omitted.

Referring to FIG. 13, in the light emitting display device 10 of this embodiment, a shield layer SL that can function as a mask for an infrared laser can be formed below a connection electrode CE.

The shield layer SL can be disposed, for example, between the connection electrode CE and a substrate 101. In this embodiment, for convenience of explanation, a situation where the shield layer SL is formed between the substrate 101 and the buffer layer 105 is taken as an example.

A penetration hole Ht through which the infrared laser can pass through can be formed in inside the shield layer SL. The shield layer SL can have characteristics that block transmission of the infrared laser, and can be formed of, for example, an opaque metal, but not limited thereto. When the shield layer SL is formed of an opaque metal, the shield layer SL can use, for example, Ag, Al, Mo, or Ti, but not limited thereto.

The penetration hole Ht of the shield layer SL can be positioned to correspond to a pattern electrode PE of the connection electrode CE. For example, the penetration hole Ht can have a size (or width or area) larger than that of the pattern electrode PE. Alternatively, the penetration hole Ht can have a size larger than that of an exposure hole Hex.

As such, by forming the shield layer SL with the penetration hole Ht located corresponding to the pattern electrode PE, a travel path of the infrared laser irradiated from the rear of the substrate 101 can be guided to a first pattern layer 152c of the pattern electrode PE by the penetration hole Ht, and the infrared laser can be blocked from proceeding to a periphery of the pattern electrode PE by the shield layer SL. Meanwhile, even if the infrared laser is irradiated to the shield layer SL, a focus of the infrared laser can be set to the first pattern layer 152c of the pattern electrode PE, so that a Joule heating in the shield layer SL may not occur substantially or be only insignificant.

By using the shield layer SL as above, it can be prevented that the infrared laser light is unintentionally irradiated to and absorbed to portions around the pattern electrode PE, causing damage to the portions (e.g., elements nearby the pattern electrode PE can be protected).

The shield layer SL can be formed, for example, in a pattern shape corresponding to a bank 160. In other words, the shield layer SL can be formed to overlap with the bank 160 and a second opening OP2.

Also, the shield layer SL can extend below a thin film transistor (T of FIG. 2) and cover the thin film transistor T (e.g., more specifically, a semiconductor layer (112 of FIG. 2)).

FIG. 14 is a cross-sectional view schematically illustrating a light emitting display device according to a third embodiment of the present invention. FIG. 14 schematically illustrates a low-potential driving voltage connection structure, like FIG. 3 of the first embodiment or FIG. 13 of the second embodiment.

In the following description, detailed descriptions of configurations identical to or similar to those of the first or second embodiments described above can be omitted.

Referring to FIG. 14, in the light emitting display device 10 of this embodiment, a connection electrode CE can be configured with a connecting electrode 151b without a pattern electrode (PE of FIG. 3), and the connecting electrode 151b can be exposed through an exposure hole Hex of a light emitting layer 165.

As such, in this embodiment, unlike the above-described first and second embodiments, the pattern electrode can be removed from the connection electrode CE, so that the connection electrode CE can be configured with the connecting electrode 151b.

Accordingly, the pattern electrode may not be provided in the exposure hole Hex of the light emitting layer 165, and the connecting electrode 151b can be exposed through the exposure hole Hex.

Accordingly, a cathode 169 can directly contact the connecting electrode 151b through the exposure hole Hex.

The connection structure can be implemented by irradiating an infrared laser of a high energy density to the pattern electrode and the pattern electrode can be completely removed or vaporized leaving behind just a hole (e.g., Hex) so that the cathode 169 can directly contact the connecting electrode 151b.

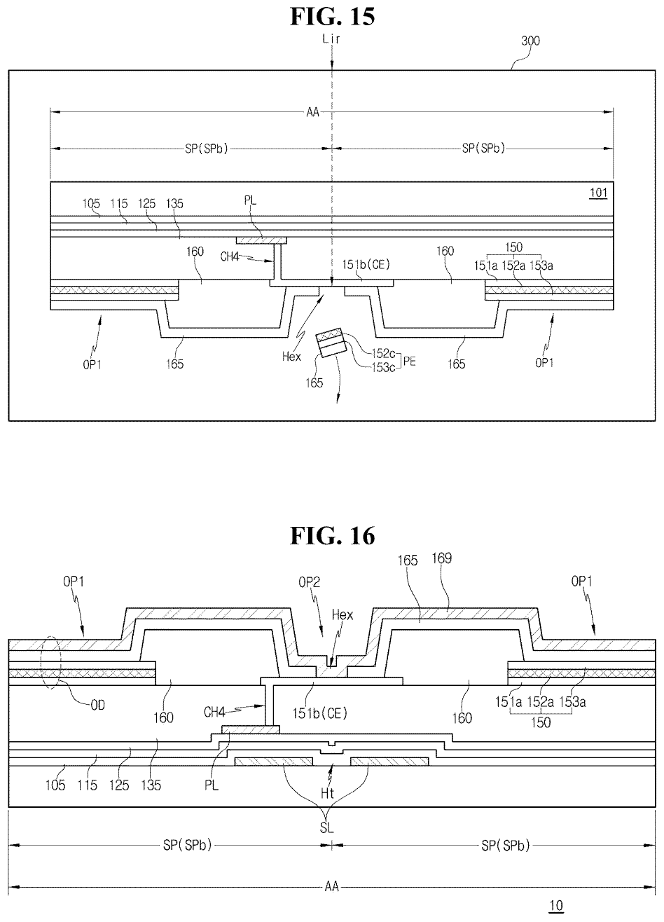

This refers to FIG. 15. FIG. 15 is a cross-sectional view illustrating a process of forming an exposure hole in a light emitting layer in manufacturing a light emitting display device according to a third embodiment of the present invention.

Referring to FIG. 15, the substrate 101 can be turned upside down so that the light emitting layer 165 faces the ground, similar to FIG. 11 of the first embodiment.

In this state, where the substrate 101 is turned over, the infrared laser Lir can be irradiated toward the substrate 101 from above the process chamber 300. At this time, the energy density of the infrared laser Lir becomes higher than that of the infrared laser Lir in the first embodiment.

In this regard, for example, under a condition that the infrared laser Lir has a wavelength of 1064 nm, a pulse width of 14 ns, and one shot is made, the energy density of the infrared laser Lir of this embodiment can be set to be about greater than 1.0 J/cm².

As such, when the infrared laser Lir having the high energy density is irradiated to the pattern electrode PE, thermal expansion of the first pattern layer 152c occurs, and the first pattern layer 152c is peeled off from the connecting electrode 151b. When the first pattern layer 152c is peeled off, the second pattern layer 153c on the first pattern layer 152c and a portion of the light emitting layer 165 covering the pattern electrode PE are peeled off together, and as a result, the pattern electrode PE and the light emitting layer 165 can be lifted off and removed. Accordingly, the exposure hole Hex that exposes the connecting electrode 151b below the pattern electrode PE can be formed in the light emitting layer 165.

As such, since the exposure hole Hex is formed by the lift-off due to irradiation of the infrared laser Lir, the exposure hole Hex can be formed in a shape corresponding to the pattern electrode PE without substantial processing errors. In other words, tighter tolerances can be provided for the exposure hole Hex so that it matches the footprint of the pattern electrode PE which has been removed.

In addition, as the exposure hole Hex is formed by the lift-off, the portion of the light emitting layer 165 located within the second opening OP2, more specifically, the portion of the light emitting layer 165 located on the connecting electrode 151b can have a substantially uniform thickness. In other words, a top surface of the light emitting layer 165 located on the connecting electrode 151b can be substantially flat.

In addition, an inner surface of the light emitting layer 165 defining the exposure hole Hex can have an inclination close to vertical. For example, the inner surface of the light emitting layer 165 around the exposure hole Hex can have an inclination of about 70 to 90 degrees.

A cathode 169 can contact the connecting electrode 151b through the exposure hole Hex of the light emitting layer 165 formed as above.

In this embodiment as above, the pattern electrode PE of the connection electrode CE and the light emitting layer 165 are removed through the lift-off operation to form the exposure hole Hex exposing the connecting electrode 151b, and the cathode 169 is in contact with the connection electrode 151b through the exposure hole Hex, so that a connection structure electrically connecting the transmission line TL and the cathode 169 can be implemented.

FIG. 16 is a cross-sectional view schematically illustrating a light emitting display device according to a fourth embodiment of the present invention. FIG. 16 schematically shows a connection structure of a low-potential driving voltage, like FIG. 14 of the third embodiment.

In the following description, detailed descriptions of configurations identical to or similar to those of the first to third embodiments described above can be omitted.

Referring to FIG. 16, in the light emitting display device 10 of this embodiment, a shield layer SL that can function as a mask for an infrared laser can be formed below a connection electrode CE.

The shield layer SL can be disposed, for example, between the connection electrode CE and a substrate 101. In this embodiment, for convenience of explanation, the situation where the shield layer SL is formed between the substrate 101 and the buffer layer 105 is taken as an example.

A penetration hole Ht through which the infrared laser light can pass through can be formed inside the shield layer SL. The shield layer SL can have characteristics that block transmission of the infrared laser light, and can be formed of, for example, an opaque metal, but not limited thereto. When the shield layer SL is formed of an opaque metal, the shield layer SL can use, for example, Ag, Al, Mo, or Ti, but not limited thereto.

The penetration hole Ht of the shield layer SL can be positioned to correspond to a pattern electrode (PE of FIG. 15) of the connection electrode CE (or an exposure hole Hex). For example, the penetration hole Ht can have a size (or width or area) larger than that of the pattern electrode.

As such, by forming the shield layer SL with the penetration hole Ht located corresponding to the pattern electrode, a travel path of the infrared laser light irradiated from the rear of the substrate 101 can be guided to a first pattern layer (152c in FIG. 15) of the pattern electrode by the penetration hole Ht, and the infrared laser light can be blocked from proceeding to a periphery of the pattern electrode by the shield layer SL.

By using the shield layer SL as above, it can be prevented that the infrared laser light is unintentionally irradiated to and absorbed to portions around the pattern electrode, causing damage to the portions (e.g., elements nearby the pattern electrode can be protected).

The shield layer SL can be formed, for example, in a pattern shape corresponding to a bank 160. In other words, the shield layer SL can be formed to overlap the bank 160 and a second opening OP2.

In addition, the shield layer SL can extend below a thin film transistor (T of FIG. 2) and cover the thin film transistor T (more specifically, the semiconductor layer (112 of FIG. 2)).

As described above, according to the embodiments of the present invention, the connection electrode is formed within the display region, the structure that connects the transmission line and the cathode through the connection electrode can be implemented, and the connection structure can be uniformly distributed at multiple positions within the display region.

Accordingly, the low-potential driving voltage can be provided to the cathode through the connection structures configured at multiple positions within the display region. Therefore, the IR rising of the low-potential driving voltage can be improved and the low-potential driving voltage can be uniformly applied, thereby improving image quality.

In addition, in implementing the connection structure of the low-potential driving voltage, the infrared laser is irradiated to the pattern electrode of the connection electrode, and through the Joule heating effect by the infrared laser irradiation, the portion of the light emitting layer covering the pattern electrode is removed to form the exposure hole exposing the pattern electrode, and the cathode is brought into contact with the exposed pattern electrode. As a different manner, the infrared laser light of high energy density is irradiated to the pattern electrode of the connection electrode, and through the lift-off by the infrared laser irradiation, the pattern electrode and the portion of the light emitting layer covering the pattern electrode are removed to form the exposure hole exposing the connecting electrode of the connection electrode, and the cathode is brought into contact with the exposed connecting electrode.

Accordingly, the contact area between the connection electrode and the cathode can be optimized as needed without substantial processing errors.

As a result, the aperture ratio of the light emitting display device can be maximized, occurrence of a residual film of the light emitting layer in the laser processing region can be prevented (that is, a substantially zero level can be achieved), and it is possible to prevent defects from occurring in layers below the light emitting layer when laser irradiated.

In addition, since the connection electrode can be formed in the same process as the anode, efficiency of process can be improved.

In addition, the shield layer having the penetration hole corresponding to the pattern electrode of the connection electrode can be formed. Accordingly, it can be prevented that the infrared laser light is unintentionally irradiated to and absorbed to portions around the pattern electrode, causing damage to the portions.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A light emitting display device, comprising:
a plurality of subpixels disposed in a display region of a substrate;
a transmission line disposed in the display region and configured to transmit a driving voltage;
a passivation layer disposed on the transmission line;
a first electrode disposed on the passivation layer;
a connection electrode disposed between two adjacent subpixels among the plurality of subpixels on the passivation layer, the connection electrode being electrically connected to the transmission line;
a bank including a first opening overlapping with the first electrode and a second opening overlapping with the connection electrode;
a light emitting layer disposed on the first electrode, the bank and the connection electrode, the light emitting layer including an exposure hole overlapping with the connection electrode; and
a second electrode disposed on the light emitting layer, the second electrode contacting the connection electrode through the exposure hole,
wherein the connection electrode includes:
a connecting electrode contacting the transmission line through a contact hole in the passivation layer; and
a pattern electrode disposed on the connecting electrode, located in the exposure hole, and contacting the second electrode, and
wherein the pattern electrode includes a first pattern layer including an opaque metal configured to absorb laser light from an infrared laser.

2. The light emitting display device of claim 1, wherein a width of the connecting electrode is greater than a width of the pattern electrode, and the connecting electrode is overlapped by a portion of the light emitting layer around the exposure hole.

3. The light emitting display device of claim 1, wherein the connecting electrode includes a transparent conductive material.

4. The light emitting display device of claim 1, wherein the pattern electrode includes a second pattern layer disposed on the first pattern layer, the second pattern layer including a transparent conductive material.

5. The light emitting display device of claim 4, wherein the first electrode has a same stack structure as the connection electrode.

6. The light emitting display device of claim 5, wherein the first electrode includes:
a first transparent conductive layer including a same material as the connecting electrode;
an opaque metal layer including a same material as the first pattern layer; and
a second transparent conductive layer including a same material as the second pattern layer.

7. The light emitting display device of claim 1, wherein the pattern electrode penetrates through the light emitting layer via the exposure hole.

8. The light emitting display device of claim 1, wherein an inner surface the exposure hole has an inclination of 70 degrees to 90 degrees, and
wherein a portion of the light emitting layer covering the connecting electrode has a uniform thickness.

9. The light emitting display device of claim 1, further comprising a shield layer below the passivation layer, and the shield layer includes a penetration hole corresponding to the exposure hole.

10. The light emitting display device of claim 9, wherein the shield layer is configured to block the infrared laser.

11. The light emitting display device of claim 1, wherein the exposure hole has a width of less than 10 um.

12. A light emitting display device, comprising:
a plurality of subpixels disposed in a display region of a substrate;
a transmission line disposed in the display region and configured to transmit a driving voltage;
a passivation layer disposed on the transmission line;
a first electrode disposed on the passivation layer;
a connecting electrode disposed between two adjacent subpixels among the plurality of subpixels on the passivation layer, the connecting electrode being electrically connected to the transmission line through a contact hole in the passivation layer;
a bank including a first opening overlapping with the first electrode and a second opening overlapping with the connecting electrode;
a light emitting layer disposed on the first electrode, the bank and the connecting electrode, the light emitting layer including an exposure hole overlapping with the connecting electrode; and
a second electrode disposed on the light emitting layer, the second electrode contacting the connecting electrode through the exposure hole,
wherein the first electrode includes:
a first transparent conductive layer includes a same transparent conductive material as the connecting electrode; and
an opaque metal layer disposed on the first transparent conductive layer, the opaque metal layer including an opaque metal configured to absorb laser light from an infrared laser.

13. The light emitting display device of claim 12, wherein the first electrode includes a second transparent conductive layer including a transparent conductive material on the opaque metal layer.

14. The light emitting display device of claim 12, wherein an inner surface of the exposure hole has an inclination of 70 degrees to 90 degrees, and
wherein a portion of the light emitting layer overlapping with the connecting electrode has a uniform thickness.

15. The light emitting display device of claim 12, further comprising a shield layer below the passivation layer, and the shield layer including a penetration hole corresponding to the exposure hole.

16. The light emitting display device of claim 15, wherein the shield layer is configured to block the infrared laser.

17. The light emitting display device of claim 12, wherein the exposure hole has a width of less than 10 um.

18. A light emitting display device, comprising:
a plurality of subpixels disposed in a display region of a substrate;
a transmission line disposed in the display region and configured to transmit a driving voltage;
a passivation layer disposed on the transmission line;
a first electrode disposed on the passivation layer;
a connection electrode disposed between two adjacent subpixels among the plurality of subpixels on the passivation layer, the connection electrode being electrically connected to the transmission line;
a bank covering an edge of the first electrode and an edge of the connection electrode;
a light emitting layer disposed on the first electrode, the bank and the connection electrode, the light emitting layer including an exposure hole overlapping with the connection electrode; and
a second electrode disposed on the light emitting layer, the second electrode contacting the connection electrode through the exposure hole,
wherein the connection electrode includes a connecting electrode contacting the transmission line through a contact hole in the passivation layer, and
wherein the first electrode includes a first transparent conductive layer including a same transparent conductive material as the connecting electrode, and an opaque metal layer disposed on the first transparent conductive layer and including an opaque metal configured to absorb laser light from an infrared laser.

19. The light emitting display device of claim 18, wherein the connection electrode includes a pattern electrode disposed on the connecting electrode, located in the exposure hole and contacting the second electrode, and
wherein the pattern electrode includes a first pattern layer including a same material as the opaque metal layer.

20. The light emitting display device of claim 19, wherein a width of the connecting electrode is greater than a width of the pattern electrode, and the connecting electrode is overlapped by a portion of the light emitting layer around the exposure hole.

21. The light emitting display device of claim 19, wherein the pattern electrode includes a second pattern layer disposed on the first pattern layer and including a transparent conductive material, and
wherein the first electrode includes a second transparent conductive layer disposed on the opaque metal layer and including a same material as the second pattern layer.

22. The light emitting display device of claim 19, wherein the pattern electrode penetrates through the light emitting layer via the exposure hole.

23. The light emitting display device of claim 18, wherein the second electrode contacts the connecting electrode through the exposure hole.

24. The light emitting display device of claim 23, wherein the first electrode includes a second transparent conductive layer including a transparent conductive material disposed on the opaque metal layer.

25. The light emitting display device of claim 18, further comprising a shield layer below the passivation layer, and the shield layer including a penetration hole corresponding to the exposure hole.

26. The light emitting display device of claim 25, wherein the shield layer is configured to block the infrared laser.

27. A display device, comprising:
a first subpixel and a second subpixel disposed on a substrate;
a light emitting layer extending across the first subpixel and the second subpixel;
a cathode electrode disposed on the light emitting layer, the cathode electrode extending across the first subpixel and the second subpixel;
a connection electrode disposed between the first subpixel and the second subpixel;
a transmission line configured to receive a driving voltage, the transmission line being electrically connected to the connection electrode,
wherein the cathode electrode is electrically connected to the connection electrode via an exposure hole in the light emitting layer.

28. The display device of claim 27, further comprising:
a pattern electrode disposed on the connection electrode, the pattern electrode penetrating through the light emitting layer via the exposure hole and contacting the cathode electrode.

29. The display device of claim 27, wherein the pattern electrode includes an opaque layer configured to absorb laser light from an infrared laser.

30. The display device of claim 27, further comprising:
a shielding layer disposed under the connection electrode, the shielding layer including a penetration hole overlapping with the exposure hole in the light emitting layer.
